(19) United States
(12) Patent Application Publication
(10) Pub. No.: US 2026/0049771 A1
(43) Pub. Date: Feb. 19, 2026

(54) THREE-DIMENSIONAL VAPOR CHAMBER ASSEMBLY STRUCTURE

(71) Applicant: TAIWAN MICROLOOPS CORP., New Taipei City (TW)

(72) Inventor: Chun-Hung LIN, New Taipei City (TW)

(21) Appl. No.: 18/891,396

(22) Filed: Sep. 20, 2024

(30) Foreign Application Priority Data
Aug. 15, 2024 (TW) 113130659

(51) Int. Cl. F28D 15/02; F28D 15/04

(52) U.S. Cl. CPC F28D 15/0275; F28D 15/0283; F28D 15/04

(57) ABSTRACT

A three-dimensional vapor chamber assembly structure includes: a housing including a first housing plate and a second housing plate, an accommodation chamber is formed between the first housing plate and the second housing plate, the second housing plate has penetrated holes, and a recessed slot is respectively formed at an outer circumference of the penetrated holes; a plurality of heat pipes correspondingly disposed in the penetrated holes, the heat pipes has an open end, the open end has a flange, the flange is disposed in the recessed slot, the heat pipe is combined with the second housing plate via a welded layer on the flange and the recessed slot; a capillary structure disposed in the accommodation chamber and attached on the housing and a working fluid is disposed in the accommodation chamber. Accordingly, a welding material is prevented from entering the accommodation chamber.

### BACKGROUND OF THE DISCLOSURE

### Technical Field

The present disclosure relates to a heat dissipation technology field, especially to a three-dimensional vapor chamber assembly structure.

### Description of Related Art

A related-art three-dimensional vapor chamber structure mainly includes a vapor chamber and a plurality of heat pipes. The heat pipes are spacedly disposed on the vapor chamber, and an accommodation chamber inside the vapor chamber mutually communicates with an inner space of each of the heat pipes, thus a rapid heat guiding and heat dissipating performance is achieved via a phase change of gasifying and liquidizing.

However, the related-art three-dimensional vapor chamber structure is provided with the heat guiding and heat dissipating performance, but disadvantages found in actual operations are as follows. Each of the heat pipes and the vapor chamber are combined by utilizing a welding material, for example a copper paste or a tin paste, various situations, for example being loosened caused by vibrations, may happen during the assembling or transporting process. Moreover, during a process of the copper paste or the tin paste being made, the copper paste or the tin paste may easily enter the accommodation chamber to affect or block a transferring path of an internal working fluid, thus the heat guiding and the heat dissipating performance becomes poor.

Accordingly, the applicant of the present disclosure has devoted himself for improving the mentioned shortages.

### SUMMARY OF THE DISCLOSURE

The present disclosure provides a three-dimensional vapor chamber assembly structure, which has advantages of having a stable assembling strength and capable of preventing a welding material from entering an accommodation chamber, and the smooth transferring of a working fluid is ensured.

Accordingly, the present disclosure provides a three-dimensional vapor chamber assembly structure, which includes a housing, a plurality of heat pipes, a capillary structure and a working fluid. The housing includes a first housing plate and a second housing plate correspondingly engaged and sealed with the first housing plate, an accommodation chamber is formed between the first housing plate and the second housing plate, the second housing plate has a plurality of penetrated holes, and a recessed slot is formed at an outer circumference of each of the penetrated holes. Each of the heat pipes is correspondingly disposed in each of the penetrated holes, each of the heat pipes has an open end, the open end has a flange, each of the flanges is disposed in each of the recessed slots, wherein each of the heat pipes is combined with the second housing plate via a welded layer on the flange and the recessed slot. The capillary structure is disposed in the accommodation chamber and attached on the housing. The working fluid is disposed in the accommodation chamber.

Advantages achieved by the present disclosure are as follows. A welding material is not required by an electrical resistance welding operation; thus, the production cost is saved. With a tightening match between the flange and the recessed slot, a welding material, for example a copper paste or a tin paste, is effectively prevented from entering the accommodation chamber, thus the heat conducting and heat dissipating performance is increased. Moreover, the manufacturing procedure is simplified, and the firmness and the liability after being assembled are ensured.

### BRIEF DESCRIPTION OF THE DRAWINGS

FIG. 1 is an exploded view showing the second housing plate, each of the heat pipes and the capillary structure according to the present disclosure;

FIG. 2 is a cross-sectional assembly view and a partially enlarged view showing the second housing plate and each of the heat pipes according to the present disclosure;

FIG. 3 is a perspective exploded view showing the three-dimensional vapor chamber assembly structure according to the present disclosure;

FIG. 4 is a perspective view showing the assembly of the three-dimensional vapor chamber assembly structure according to the present disclosure; and

FIG. 5 is a cross-sectional view showing the assembly of the three-dimensional vapor chamber assembly structure according to the present disclosure.

### DETAILED DESCRIPTION

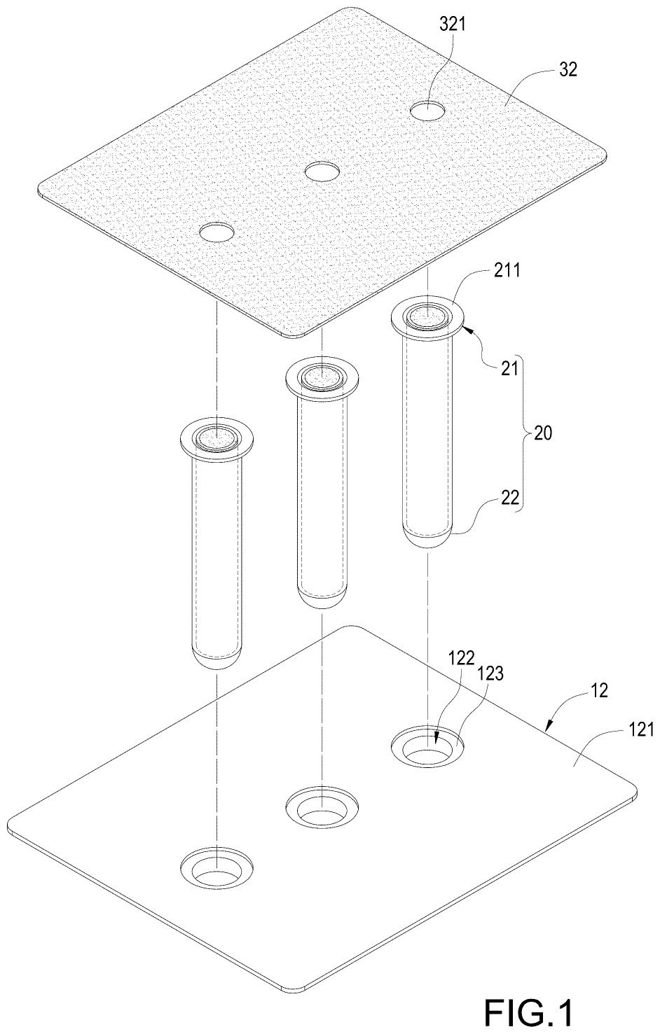

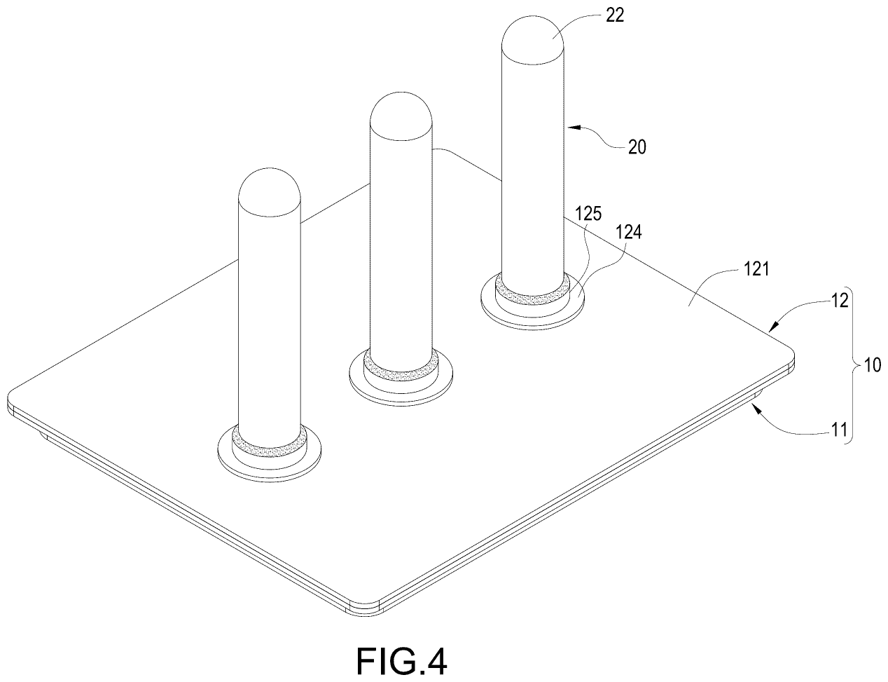

Please refer from FIG. 1 to FIG. 5, the present disclosure provides a three-dimensional vapor chamber assembly structure, which includes a housing 10, a plurality of heat pipes 20, a capillary structure 30 and a working fluid 40.

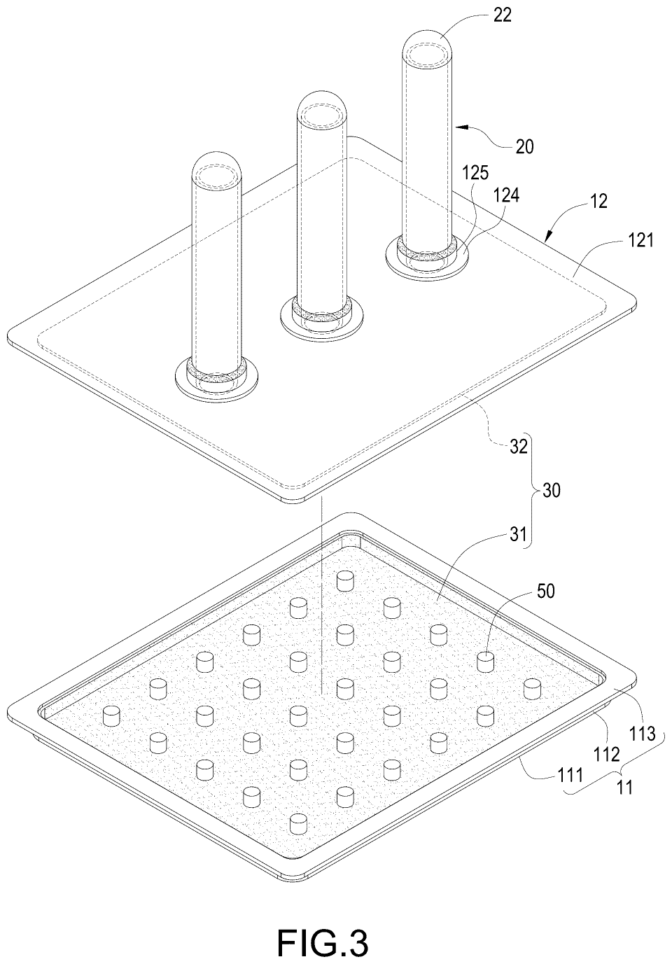

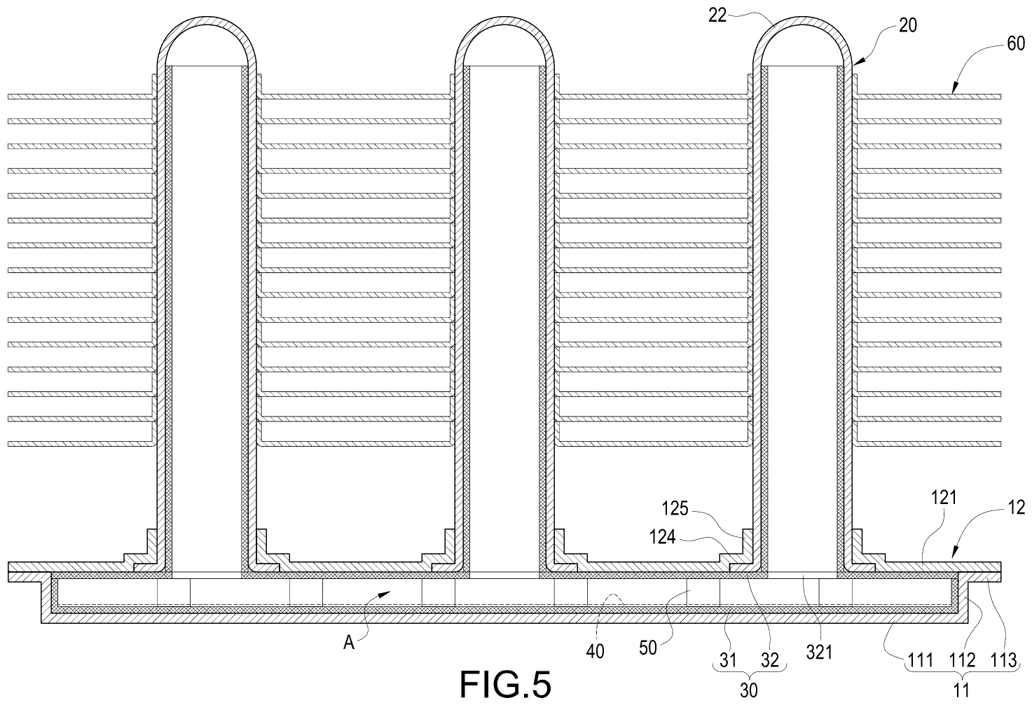

Please refer to FIG. 3 and FIG. 5, the housing 10 mainly includes a first housing plate 11 and a second housing plate 12. The first housing plate 11 and the second housing plate 12 are made of a material having a desirable heat conducting property, for example copper, aluminum, magnesium or an alloy thereof. The first housing plate 11 mainly includes a bottom plate 111 and a surrounding plate 112 extended and upwardly bent from a periphery of the bottom plate 111, and a bending edge 113 is outwardly extended from one end of the bottom plate 111 away from the surrounding plate 112.

The second housing plate 112 mainly includes a top plate 121. The second housing plate 12 and the first housing plate 11 are engaged by the top plate 121 being sealed with the bending edge 113, thus an accommodation space A is formed between the first housing plate 11 and the second housing plate 12.

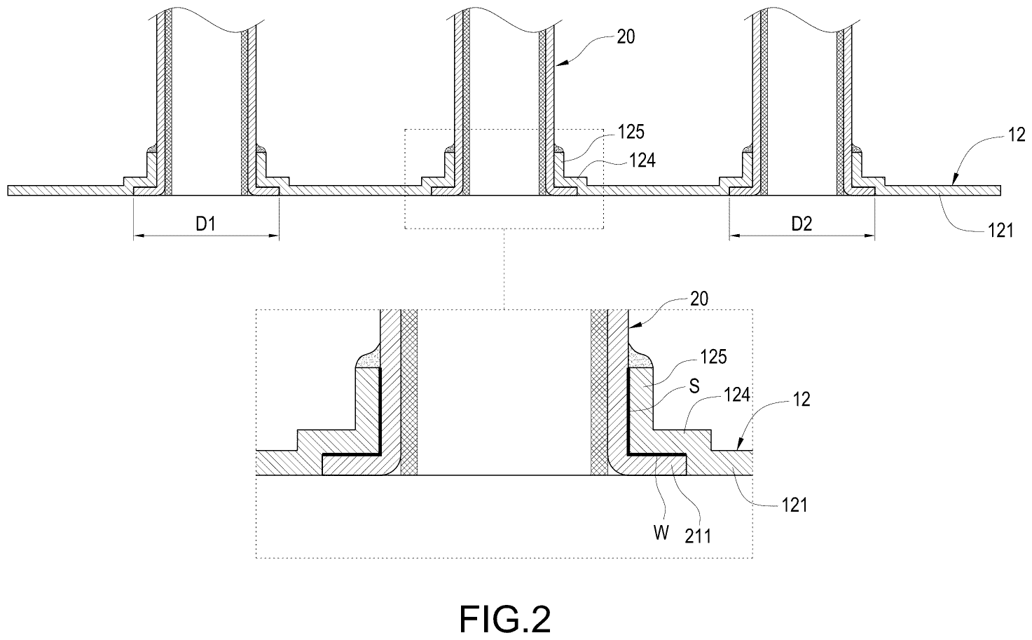

Please refer to FIG. 1 and FIG. 2, a plurality of penetrated holes 122 are spacedly formed at an inner side of the top plate 121 of the second housing plate 12. A recessed slot 123 is formed at an outer circumference of each of the penetrated holes 122. A protrusion 124 higher than an outer surface of the top plate 121 is formed at a location corresponding to the recessed slot 123. A surrounding wall 125 is upwardly extended from a circumference of each of the penetrated holes 122. In some embodiments, the recessed slot 123 is a circular recessed slot and has an inner diameter D1.

Each of the heat pipes 20 is disposed corresponding to each of the penetrated holes 122. Each of the heat pipes 20 has an open end 21 and a close end 22. A flange 211 is disposed at the open end 21. Each of the flanges 211 is disposed in each of the recessed slots 123. A bottom surface of the flange 211 is aligned with an inner surface (an adjacent surface) of the top plate 121 or is lower than the inner surface of the top plate 121 (in other words, forming a concave status relative to the inner surface of the top plate 121). In some embodiments, the flange 21 is a circular flange and has an outer diameter D2. The outer diameter D2 of the flange 211 is greater than or equal to the inner diameter D1 of the recessed slot 123, thus an interfering match or a tightening match is formed between the flange 211 and the recessed slot 123. The flange 211 is extended from the open end 21 of the heat pipe 20 with a diameter expanding manner, and the flange 211 is arranged to be perpendicular to a central line of the heat pipe 20.

When being assembled, the close end 22 of the heat pipe 20 passes the penetrated hole 122 and the surrounding wall 125 of the second housing plate 12, and the flange 211 is mounted in the recessed slot 123, a welded layer W is formed on the flange 211 and the recessed slot 123 by utilizing a welding equipment or a jig (not shown in figures), thus each of the heat pipes 20 is combined with the second housing plate 12. In some embodiments, a point welding machine is used to process a welding operation, the flange 211 of the heat pipe 20 and a wall plate of the recessed slot 123 of the second housing plate 12 are pressed to be tightly connected, and a current is conducted to make the connected location be melted via an effect of electrical resistance heat, and the welded layer W is formed after being cooled.

Subsequently, a welding material is distributed on the heat pipe 20 and the surrounding wall 127 with a soft welding or a hard welding manner, and each of the welding materials is filled in a gap between the heat pipe 20 and the surrounding wall 125 with a heating manner to form a sealed layer S. Welding materials of the soft welding manner are zinc, tin or lead in a paste state. Welding materials of the hard welding manner are copper, aluminum or magnesium in a paste state.

Please refer from FIG. 3 to FIG. 5, the capillary structure 30 is disposed in the accommodation chamber A. The capillary structure 30 is configured by a material having a good capillary absorbing capability, for example a metal woven net, sintered porous powders or fiber bundles. The shape the capillary structure 30 is similar to the shape of the housing 10. In some embodiments, the capillary structure 30 mainly includes a lower capillary structure 31 and an upper capillary structure 32. The lower capillary structure 31 is attached on the first housing plate 11, and a thermal diffusion welding is processed to make the lower capillary structure 31 be fastened on an inner surface of the first housing plate 11. The upper capillary structure 32 is attached on the second housing plate 12, and a thermal diffusion welding is processed to make the upper capillary structure 32 be fastened on an inner surface of the second housing plate 12. The upper capillary structure 32 has a plurality of through holes 321. The through holes 321 of the upper capillary structure 32 are substantially arranged corresponding to the heat pipe 20, and the upper capillary structure 32 and a capillary structure of the heat pipe 20 mutually contact with each other.

The working fluid 40 may be pure water. The working fluid 40 is filled in the accommodation chamber A, and a gas discharge port sealing operation is processed to make the accommodation chamber A be a vacuum accommodation chamber.

In some embodiments, the three-dimensional vapor chamber assembly structure of the present disclosure further includes a plurality of support columns 50. Each of the support columns 50 is spacedly distributed in the accommodation chamber A, and vertically disposed between the first housing plate 11 and the second housing plate 12.

In some embodiments, the three-dimensional vapor chamber assembly structure of the present disclosure further includes a heat dissipating fin set 60. The heat dissipating fin set 60 is sheathed with each of the heat pipes 20. The heat dissipating fin set 60 includes a plurality of heat dissipating fins mutually stacked with each other.

While this disclosure has been described by means of specific embodiments, numerous modifications and variations may be made thereto by those skilled in the art without departing from the scope and spirit of this disclosure set forth in the claims.

What is claimed is:

1. A three-dimensional vapor chamber assembly structure, comprising:
a housing, comprising a first housing plate and a second housing plate correspondingly engaged and sealed with the first housing plate, wherein an accommodation chamber is defined between the first housing plate and the second housing plate, the second housing plate comprises a plurality of penetrated holes, and a recessed slot is defined on an outer circumference of each of the penetrated holes;
a plurality of heat pipes, correspondingly disposed in the penetrated holes, each of the heat pipes comprising an open end, wherein the open end comprises a flange, the flanges is disposed in the recessed slot, and each of the heat pipes is combined with the second housing plate via a welded layer on the flange and the recessed slot;
a capillary structure, disposed in the accommodation chamber and attached on the housing, and
a working fluid, disposed in the accommodation chamber.

2. The three-dimensional vapor chamber assembly structure according to claim 1, wherein the welded layer is formed via an electrical resistance welding manner.

3. The three-dimensional vapor chamber assembly structure according to claim 1, wherein the second housing plate comprises a top plate, and a protrusion higher than an outer surface of the top plate is disposed at a location corresponding each of the recessed slots.

4. The three-dimensional vapor chamber assembly structure according to claim 1, wherein the recessed slot is a circular recessed slot and comprises an inner diameter, the flange is a circular flange and comprises an outer diameter, and the outer diameter of the flange is greater than or equal to the inner diameter of the recessed slot.

5. The three-dimensional vapor chamber assembly structure according to claim 1, wherein the flange extends from the open end of the heat pipe with a diameter expanding manner, and the flange is arranged to be perpendicular to a central line of the heat pipe.

6. The three-dimensional vapor chamber assembly structure according to claim 1, wherein a surrounding wall is extended from a circumference of each of the penetrated holes, and each of the heat pipes passes the surrounding wall.

7. The three-dimensional vapor chamber assembly structure according to claim 6, wherein a sealed layer is formed between each of the heat pipes and each of multiple surrounding walls.

8. The three-dimensional vapor chamber assembly structure according to claim 7, wherein the sealed layer is formed via a soft welding manner or a hard welding manner.

9. The three-dimensional vapor chamber assembly structure according to claim 1, further comprising a plurality of support columns, each of the support columns is spacedly disposed in the accommodation chamber, and vertically disposed between the first housing plate and the second housing plate.

10. The three-dimensional vapor chamber assembly structure according to claim 1, further comprising a heat dissipating fin set sheathing each of the heat pipes.
